(19) United States
(12) Patent Application Publication
(10) Pub. No.: US 2017/0170377 A1
(43) Pub. Date: Jun. 15, 2017

(54) High Heat-dissipation LED Substrate and High Heat-dissipation LED Package

(71) Applicant: A-Flex Technologies Co., Ltd., Gongqing (CN)

(72) Inventor: Qi HUANG, Gongqing (CN)

(73) Assignee: A-Flex Technologies Co., Ltd., Gongqing (CN)

(21) Appl. No.: 14/967,361

(22) Filed: Dec. 14, 2015

(51) Int. Cl. H01L 33/64; H01L 25/075; H01L 33/54

(52) U.S. Cl. CPC H01L 33/642; H01L 33/54; H01L 25/0753; H01L 2933/0075

(57) ABSTRACT

The present invention relates to a high heat-dissipation LED substrate and a high heat-dissipation LED package using the substrate. The substrate comprises an insulating plate, a upper copper-cladding layer and a lower copper-cladding layer respectively provided on the upper and lower sides of the insulating plate; both the upper copper-cladding layer and the lower copper-cladding layer comprise heat dissipation areas and circuit areas mutually isolated; the insulating plate is provided with heat-conducting copper posts connected to the upper and lower heat dissipation areas and electric copper posts connected to the upper and lower circuit areas; the cross section of the copper post is round, 8-shaped or quincuncial; the circuit area surface of the upper copper-cladding layer is treated by roughening, and the heat dissipation area surface of the lower copper-cladding layer is provided convex-concave structures.

### TECHNICAL FIELD

The present invention relates to a high heat-dissipation LED substrate and a high heat-dissipation LED package using the high heat-dissipation LED substrate.

### BACKGROUND

Light emitting diodes (LED) very accord with the requirement of the low-carbon economy currently, due to its such features as high energy-saving efficiency, long service life and high reliability, and thus are widely used, especially in lighting and display fields. However, the heat dissipation of LED devices is a prominent problem, and poor heat dissipation will lead to an increase of LED junction temperature, thus resulting in low luminous efficacy, shortened service life, high heat productivity and other problems. Therefore, how to control the LED junction temperature is a problem that needs to be addressed urgently.

The LED junction temperature has a lot to do with the beat dissipation capability of its package; under the same conditions, the higher heat dissipation capability indicates a smaller thermal resistance, a lower temperature, and an increased direct proportion of the luminous flux and the current. The LED thermal resistance is divided into the internal thermal resistance of the material and the interface thermal resistance, and the internal thermal resistance of the material is mainly from the heat dissipation substrate and heat sink structure; the function of the heat dissipation substrate is to absorb the heat produced by the chip and to transfer the heat to the heat sink, thus realizing a heat exchange with the outside. Commonly used heat dissipation substrates include silicon substrate, metal (such as aluminum, copper) substrate, ceramic (such as AlN, SiC) substrate and composite substrate, etc., but all of the traditional substrates have a problem of poor heat dissipation effect, resulting in reduced service life of the package.

### SUMMARY OF INVENTION

To solve the above problem in existing technology, the first purpose of the present invention is to provide a high heat-dissipation LED substrate, with significantly improved heat dissipation effect, favorable to keep the junction temperature in reasonable range; the second purpose of the present invention is to provide a high heat-dissipation LED package, having strong heat dissipation capacity, high luminous efficacy and other benefits.

The technical solutions of the present invention are as follows:

A high heat-dissipation LED substrate comprises an insulating plate, wherein the upper surface of the insulating plate is provided with a upper copper-cladding layer and the lower surface thereof is provided with a lower copper-cladding layer, both the upper copper-cladding layer and the lower copper-cladding layer are divided into heat dissipation areas and circuit areas mutually isolated; the insulating plate is provided with a number of heat-conducting copper posts and electric copper posts that vertically penetrate the insulating plate; the upper ends of the heat-conducting copper posts are connected to the heat dissipation area of the upper copper-cladding layer, and the lower ends thereof are connected to the heat dissipation area of the lower copper-cladding layer; the upper ends of the electric copper posts are connected to the circuit area of the upper copper-cladding layer, and the lower ends thereof are connected to the circuit area of the lower copper-cladding layer; the circuit area surface of the upper copper-cladding layer is a roughened surface with a roughening treatment, while the heat dissipation area surface of the upper copper-cladding layer is a smooth surface without a roughening treatment, but also can be a roughened surface with a roughening treatment, more beneficial to improving the heat dissipation capacity.

Preferably, some part of the circuit area of the upper copper-cladding layer can be provided with a soldering-suitable metal layer, convenient to perform soldering for relevant lines; and some other part can be provided with a soldering-mask ink layer, favorable to the soldering operation for the soldering-suitable area, thus preventing false soldering.

Preferably, the material of the soldering-suitable metal layer can be one or snore of nickel, silver, and gold.

Preferably, the roughening method used for the circuit area surface of the upper copper-cladding layer can be one or more of mechanical roughening method, electrolytic roughening method and corrosive roughening method.

Preferably, the heat dissipation area surface of the lower copper-cladding layer is generally planar, with convex-concave structures. For example, the heat dissipation area surface of the lower copper-cladding layer can be provided with a number of mutually parallel straight grooves, or provided with a number of vertically and horizontally interlaced straight grooves. The heat dissipation area surface is provided with convex-concave structures, not only effectively increasing the surface area, but also capable of forming a number of local air circulations, thereby significantly improving the effect of thermal convection, while the straight grooves allow the surrounding cold air flow into the central part of the heat dissipation area along the grooves, thus realizing more effective thermal convection.

Preferably, the building method of the heat-conducting and electric copper posts is as follows: firstly drilling through holes at proper positions of the insulating plate, depositing a conductive carbon layer on the hole wall, then performing plating, to form the heat-conducting and electric copper posts, thus realizing the connection of the heat-conducting and electric copper posts to the corresponding heat dissipation areas and circuit areas.

The specific implementation process of the building method above mentioned can be drilling through holes at proper positions of the insulating plate, depositing a conductive carbon layer on the hole wall, then performing plating on the surface of the carbon layer; a conductive carbon layer is formed on the hole wall, thus, along with the plating layer is thickened on the carbon layer, copper posts are formed to fill the corresponding through holes, and the upper and lower ends of the copper posts are connected to the surrounding copper-cladding layers through the formed plating layers, so as to achieve the connection between the heat-conducting copper posts and the corresponding heat dissipation areas, and the connection between the electric copper posts and the corresponding circuit areas. The shape of the copper posts (including cross-sectional shape) is defined by the space shape of the through holes the insulating plate.

The cross sections of the through holes can be round or non-round.

When the cross sections of the through holes are non-round, the cross sections of the heat-conducting copper posts and the electric copper posts are preferably 8-shaped or quincuncial.

Preferably, when the cross sections of the copper posts are round, the diameter is 0.15-4 mm; when the cross sections of the heat-conducting copper posts are 8-shaped or quincuncial, the diameter of each continuous circular arc constituting, the 8-shaped or quincuncial form is preferably 0.15-4 mm.

For any of the foregoing high heat-dissipation LED substrates, the insulating plate preferably has any group of the following features:

(a) Heat conductivity is 80-160 W/(m·K), expansion coefficient is 5-6 m/K, and thickness is 0.1-0.4 mm; the substrate made of this, kind of insulating plate can be well adapted to the LED package with the chips normally-mounted.

(b) Heat conductivity is 80-160 W/(m·K), expansion coefficient is 8-10 m/K, and thickness is 0.1-0.4 mm; the substrate made of this kind of insulating plate can be well adapted to the LED package with the chips reversely-mounted.

The present invention also provides a high heat-dissipation LED package, comprising one or more high heat-dissipation LED unit(s), the high heat-dissipation LED unit comprises a high heat-dissipation substrate unit and a LED chip mounted on the high heat-dissipation substrate unit; the outside of the LED chip is provided with a transparent protection layer, the high heat-dissipation substrate unit uses any of the high heat-dissipation LED substrates according to the present invention, and the high heat-dissipation LED substrate is required to contain at least one of the heat-conducting copper posts and at least two of the electric copper posts. The LED chip is located on the heat dissipation area of the upper copper-cladding layer and the positive and negative poles thereof are respectively connected to one of the electric copper posts. When there are a plurality of high heat-dissipation LED units, the high heat-dissipation substrate units of all of the high heat-dissipation LED units respectively correspond to the different areas of the same high heat-dissipation LED substrate, that is, a number of high heat-dissipation LED units can be made on the same substrate, then a partition can be done among the high heat-dissipation LED units as required, to form a high heat-dissipation LED package containing only one high heat-dissipation LED unit.

Preferably, molded resin can be filled between the LED chip and the corresponding transparent protection layer.

Preferably, the LED chip and'the heat dissipation area of the upper copper-cladding layer under it are bonded together by a high thermal conductive binder.

The beneficial effects of the present invention are as follows:

Through the provision of heat-conducting copper posts that connect the heat dissipation area of the upper copper-cladding layer and the heat dissipation area of the lower copper-cladding, layer, both sides of the substrate have heat dissipation capacity, thus greatly improving the heat dissipation area, the good thermal conductivity of the copper posts makes the heat, produced by the chips in operating, capable of being transferred rapidly to the lower copper-cladding layer and then dissipated, so as to ensure the junction temperature within the normal range.

Due to the concave-convex, heat dissipation area surface of the lower copper-cladding layer, it not only in the heat dissipation area, but also can form local air circulations, favorable to improve the speed and capacity of heat dissipation, thereby guaranteeing that the LED chips operate at normal temperatures.

Through the use of such non-round shape as 8-shaped or quincuncial, it can prevent the copper posts and the insulating plate from relative rotation. The insulating plate and the copper posts are respectively made from different materials, with different expansion coefficients, the process cit thermal expansion and contraction will damage the binding between the copper posts and the insulating plate, the bonding force, after a long-term use, will be decreased significantly, even the copper posts and the insulating plate are stripped from each other. When the copper posts with non-round cross sections are used, it can significantly reduce the descending degree of the bonding force, and even though the copper posts and the insulating plate are stripped from each other, there is no relative rotation between them, thus obviously extending the service life of the substrate and significantly improving the reliability of the substrate.

The circuit area surface of the upper copper-cladding layer is treated by roughening, not only favorable to improve the capacity of heat dissipation, but also helpful to increase the surface adhesive force, thereby making the binding force greater among, the gold threads, fulmargin and insulating glue etc. with the substrate during subsequent package.

Under the condition that the heat dissipation area surface of the upper copper-cladding layer is also treated by roughening, it can not only improve the heat dissipation capacity, but also make the emitted light become soft, meanwhile, it is also favorable to reduce the heat reflection amount.

### BRIEF DESCRIPTION OF DRAWINGS

FIG. 1 is a structural diagram for the high heat-dissipation. LED substrate of the present invention;

FIG. 2 is a structural diagram for the high heat-dissipation LED unit of the lead-type substrate of the present invention;

FIG. 3 is a structural diagram for the high heat-dissipation LED unit of the reverse-type substrate of the present invention;

FIG. 4 is a manufacturing process flowchart of the present invention;

FIG. 5 is a cross-sectional schematic for the heat-conducting copper posts of one embodiment of the present invention;

FIG. 6 is a cross-sectional schematic for the heat-conducting copper posts of another embodiment of the present invention.

### DETAILED DESCRIPTION OF THE INVENTION

The following is a further explanation of the present invention based on the drawings.

See FIG. 1, a high heat-dissipation LED substrate 1 (which can be called substrate 1 for short), comprises an insulating plate 2; the upper surface of the insulating plate 2 is provided with a upper copper-cladding layer 3 and the lower surface thereof is provided with a lower copper-cladding layer 4, both the upper copper-cladding layer 3 and the lower copper-cladding layer 4 are divided into heat dissipation areas and circuit areas mutually isolated; the circuit areas can be the form of printed circuits, and the specific circuit construction can be designed according to actual needs. The insulating plate 2 is provided with a number of heat-conducting copper posts 5 and electric copper posts 6 that vertically penetrate the insulating plate 2; the upper ends of the heat-conducting copper posts 5 are connected to the heat dissipation area of the upper copper-cladding layer 3, and the lower ends thereof are connected to the heat dissipation area of the lower copper-cladding layer 4, thereby transferring the heat from the upper copper-cladding layer 3 to the lower copper-cladding layer 4. The upper ends of the electric copper posts 6 are connected to the circuit area of the upper copper-cladding layer 3, and the, lower ends thereof are connected to the circuit area of the lower copper-cladding layer 4, thereby realizing the electrical continuity of the upper and lower circuit areas. Power connection ends (corresponding to the pins of the LED package), let out from the lower circuit area, are connected to the power supply, then the power is connected to the upper circuit area through the electric copper posts 6.

The circuit area surface of the upper copper-cladding layer 3 is a roughened surface formed with a roughening treatment, while the heat dissipation area surface of the upper copper-cladding layer 3 is a smooth surface without a roughening treatment, but also can be a roughened surface formed with a roughening treatment, more beneficial to improving the heat dissipation capacity.

Some pan of the circuit area of the upper copper-cladding layer 3 can be provided with a soldering-suitable metal layer, convenient to perform soldering for relevant lines; and other pan of the circuit area of the upper copper-cladding layer 3 can be provided with a soldering-mask ink layer, favorable to the soldering operation for the soldering-suitable area, thus preventing false soldering.

The material of the soldering-suitable metal layer can be one or more of nickel, silver, and gold.

The roughening method used for the circuit area surface of the upper copper-cladding layer 3 can be one or more of mechanical roughening method, electrolytic roughening method and corrosive roughening method.

The heat dissipation area surface of the lower copper-cladding layer 4 is generally planar, with convex-concave structures. For example, the heat dissipation area surface of the lower copper-cladding layer 4 can be provided with a number of mutually parallel straight grooves, or provided with a number of vertically and horizontally interlaced straight grooves. The heat dissipation area surface is provided with convex-concave structures, not only effectively increasing the surface area, but also capable of forming a number of local air circulations, thereby significantly improving the effect of thermal convection, while the straight grooves allow the surrounding cold air flow into the central part of the heat dissipation area along the grooves, thus realizing more effective thermal convection.

Preferably, the building method of the heat-conducting copper posts 5 and electric copper posts 6 is as follows: firstly drilling through holes at proper positions of the insulating plate 2, depositing a conductive carbon layer on the hole wall, then performing plating, to form the heat-conducting copper posts 5 and electric copper posts 6, thus realizing the connection of the beat-conducting copper posts 5 and electric copper posts 6 to the corresponding, heat dissipation areas and circuit areas.

The specific implementation process can be: drilling through holes at proper positions of the insulating plate 2, depositing a conductive carbon layer on the hole wall, then performing plating to the surface of the carbon layer. A conductive carbon layer is formed on the hole wall of the insulating plate 2, thus a plating layer is formed on the carbon layer and is gradually thickened along with the proceeding of plating, finally copper posts are formed to fill the corresponding through holes, and the upper and lower ends of the copper posts are respectively connected to the upper copper-cladding layer 3 and the lower copper-cladding layer 4, so as to achieve the connection of the heat-conducting copper posts 5 and the electric copper posts 6 respectively to the corresponding heat dissipation areas and the corresponding circuit areas. The shape of the copper posts (including cross-sectional shape) is defined by the space shape of the through holes on the insulating plate 2

The cross sections of the through holes can be round or non-round. When the cross sections of the through holes are non-round, the cross sections of the heat-conducting copper posts 5 and the electric copper posts 6 are preferably 8-shaped or quincuncial.

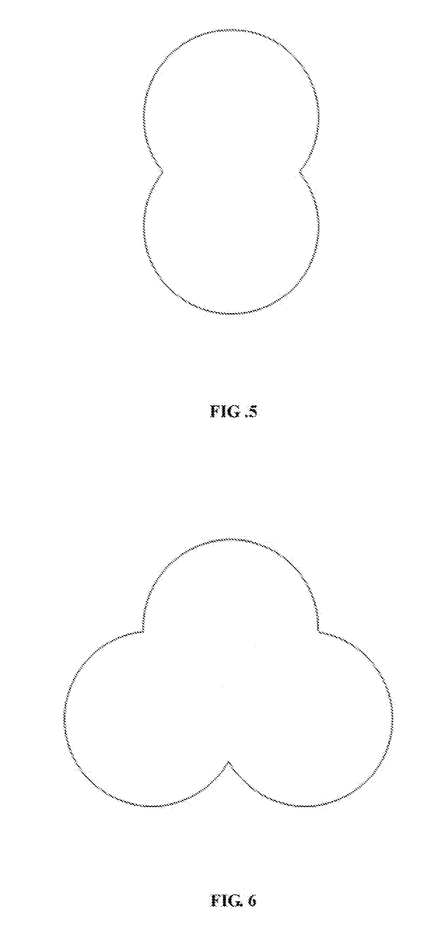

In the embodiment as shown in FIG. 5, the cross section of the through holes on the insulating plate 2 is 8-shaped; a laser capable of drilling round holes is used to drill two holes, and parts of these two holes are overlapped each other, thereby forming a 8-shaped hole.

In the embodiment as shown in FIG. 6, the cross section of the through holes on the insulating plate 2 is quincuncial; a laser capable of drilling round holes is used to drill three holes, the central points of which are distributed on the same circle with equal spacing, and three:round holes are overlapped on their central area, thereby forming a quincuncial hole with three petals. When a quincuncial hole with more petals is needed, more holes can be drilled, the central points of the holes are distributed on the same circle with equal spacing, the round holes are overlapped on their central area, thereby forming a quincuncial hole with more than three petals.

When the cross sections of the copper posts are round, the diameter is 0.15-4 mm; when the cross sections of the heat-conducting copper posts 5 are 8-shaped or quincuncial, the diameter of each continuous circular arc constituting the 8-shaped or quincuncial form is preferably 0.15-4 mm.

The insulating plate 2 has any group of the following features:

(a) Heat conductivity is 80-160 W/(m·K), expansion coefficient is 5-6 m/K and thickness is 0.1-0.4 mm; the substrate made of this kind of insulating plate can be well adapted to the LED package with the chips normally-mounted.

(b) Heat conductivity is 80-160 W/(m·K), expansion coefficient is 8-10 m/K, and thickness is 0.1-0.4 mm; the substrate made of this kind of insulating plate can be well adapted to the LED package with the chips reversely-mounted, the reverse structure that faces down makes the P-N Junction closer to the heat sink, thus reducing the expansion coefficient, improving the heat dissipation features and extending the service life of the chip.

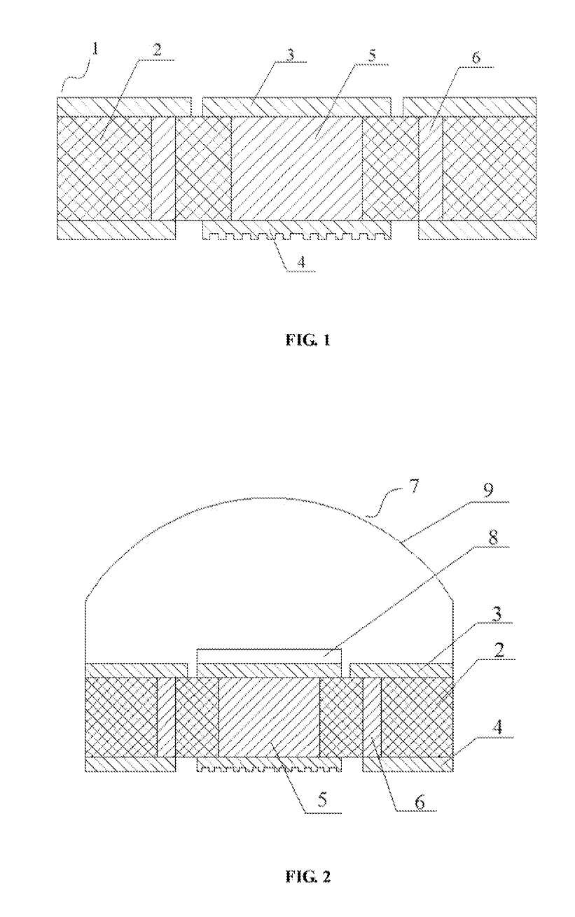

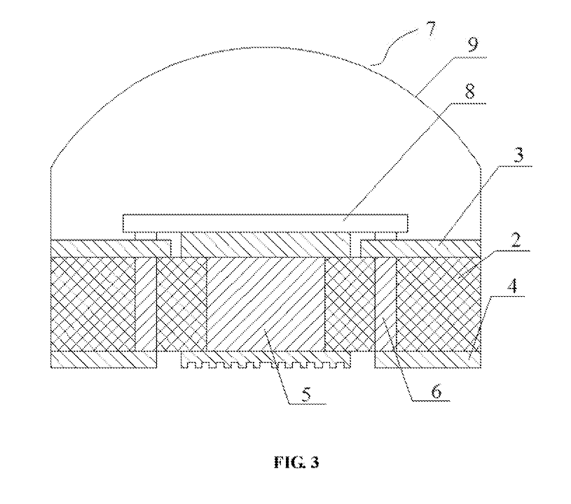

As shown in FIG. 2 and FIG. 3, the present invention also provides a high heat-dissipation LED package, comprising one or more high heat-dissipation LED unit(s) 7; the high heat-dissipation LED unit 7 comprises a high heat-dissipation substrate unit and a LED chip 8 mounted on the high heat-dissipation substrate unit; the outside of the LED chip 8 is provided with a transparent protection layer 9; the high heat-dissipation substrate unit uses any of the high heat-dissipation LED substrates 1 according to the present invention, and the high heat-dissipation LED substrate 1 is required to contain at least one of the heat-conducting copper posts 5 and at least two of the electric copper posts 6. The LED chip 8 is located on the heat dissipation area of the upper copper-cladding layer 3 and the positive and negative poles thereof are electrically connected to one of the electric copper posts 6 respectively. When there are a plurality of high heat-dissipation LED units 7, the high heat-dissipation substrate units of all of the high heat-dissipation LED unit 7 respectively correspond to the different areas of the same high heat-dissipation LED substrate 1, that is, a number of high heat-dissipation LED units 7 can be made on the same substrate 1, then a partition can be done among the high heat-dissipation LED units 7 as required, to form a high heat-dissipation LED package containing only one high heat-dissipation LED unit 7.

Molded resin can be filled between the LED chip 8 and the transparent protection layer 9.

The LED chip 8 and the heat dissipation area of the upper copper-cladding layer 3 under it are bonded together by a high thermal conductive binder.

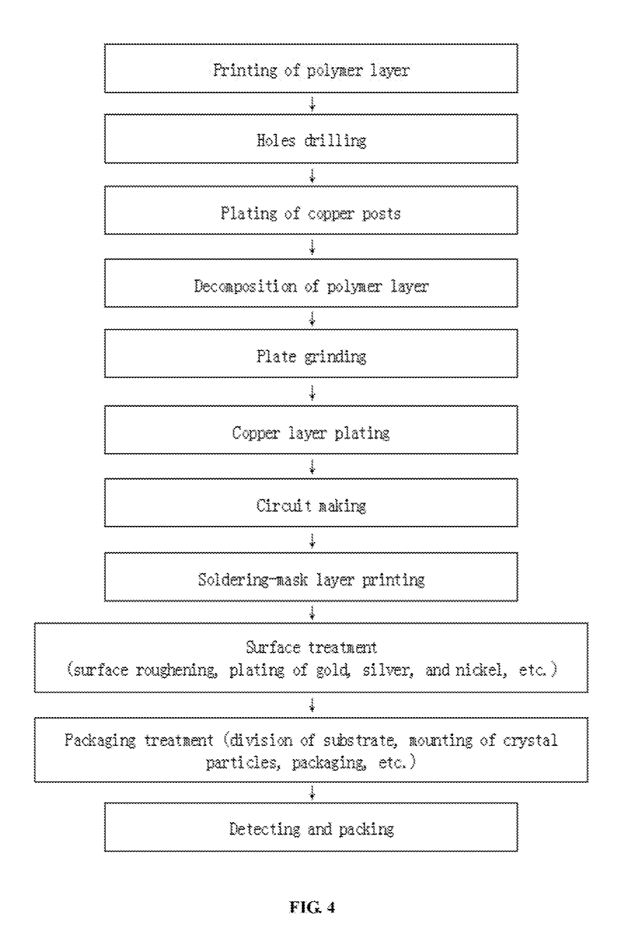

See FIG. 4, the substrate 1 and the LED package of the present invention can be made according to the following methods, including:

Printing of polymer layer: a material of polymer resin is printed on the surfaces of the upper copper-cladding layer 3 and the lower copper-cladding layer 4, to form a polymer layer.

Holes drilling: a mold of predefined circuit pattern is used to mask the polymer layer; through such processes as exposure, developing and curing, a portion of the polymer layer is etched off, to expose the positions to be drilled on the copper-cladding layer surface of the substrate 1, then through boles, the cross sections of which are in round, 8-shaped or quincuncial form or in other forms and penetrate the substrate 1, are drilled on the copper-cladding layer surface as required.

Copper posts plating: the through holes are tilled with copper by means of plating, to form the heat-conducting posts 5 and electric copper posts 6 that connect the upper copper-cladding layer 3 and the lower copper-cladding layer 4 Before the plating, a carbon layer is deposited on the walls of the through holes.

Polymer layer decomposition agents are used to decompose the polymer layer,

Plate grinding: the surfaces of the upper and lower ends of the copper posts, the upper copper-cladding layer 3 and the lower copper-cladding layer 4 are ground flush after the plating, to keep the surfaces of the copper posts, the upper copper-cladding layer 3 and the lower copper-cladding layer 4 consistently smooth.

Copper layer plating: a prefabricated mold is used to plate a layer of copper on the upper copper-cladding layer 3 and the lower copper-cladding layer 4, to increase the thicknesses of corresponding copper-cladding layers of the insulating plate 2.

Circuit making: through such processes as chemical cleaning, dry film pasting, expos ire and developing, the needed circuits can be made by etching the corresponding surfaces of the upper copper-cladding layer 3 and the lower copper-cladding layers 4.

Soldering-mask layer printing; a soldering-mask ink is applied onto the copper layer where a solder mask is needed

Surface roughening the upper copper-cladding layer 3 is treated by roughening, and the method can be mechanical roughening method, electrolytic roughening method and corrosive roughening method.

The concave-convex surface of the lower copper-cladding layer 4 can be formed by means of roughening, and also can be formed by etching, machining or other ways; the exact shape of the concave-convex part can be designed according to the requirements of facilitating the processing and improving the heat dissipation efficiency.

Sputtering coating of soldering-suitable metal layer: a soldering-suitable metal layer is provided on the upper copper-cladding layer 3 by means of sputtering as required, and the soldering-suitable metal layer is one or more of nickel layer, silver layer, and gold layer, to provide a place for soldering electronic components.

The making of the high heat-dissipation LED substrate 1 is finished according to the steps above mentioned.

Then the following steps are continued, to make the corresponding high heat-dissipation LED package.

Division of substrate: the substrate 1 is divided into a number of areas, to form a number of substrate units corresponding to the LED units; each of the substrate units is provided with at least one heat-conducting copper post 5 and at least two electric copper posts 6, and the heat-conducting copper post 5 is located close to the center of the substrate unit.

Mounting of chips: LED chips 8 are mounted above the heat-conducting copper posts 5; when the chips are normally mounted, gold threads are used to connect the chips with the electric copper posts 6 on the both sides, and the gold threads are externally coated by gold thread protection glue; when the chips are reversely mounted, they are connected to the electric copper posts 6 on the both sides; the bottoms of the LED chips are filled with solid crystal glue and heat-conducting

Package surface roughening: the transparent protection layers 9 used for packaging are made into concave-convex surfaces.

Packaging: the substrate units are, packaged by use of the transparent protection layers 9, while filling the mold with molded resin during the coverage, to form LED package units.

Partition (if necessary): a plurality of package units are partitioned from each other, to obtain the high heat-dissipation LED units 7 as shown in FIG. 2.

Packing: the high heat-dissipation LED packages that are finished are packed to be sold.

The substrate provided by the present invention features low cost, high reliability and wide application scope. The concave-convex structure on the heat dissipation area surface of the lower copper-cladding layer 4 is not limited to the structure as shown in the drawings, and can be any reasonable shape, such as semicircular convex or concave, wave pattern, sawtooth shape, and so on. In the same way, the shape of the heat-conducting copper posts 5 of the present invention can also be set into other proper shapes similar to the shapes above mentioned,

1. A high heat-dissipation LED substrate, comprising an insulating plate, wherein the upper surface of the insulating plate is provided with a upper copper-cladding layer and the lower surface thereof is provided with a lower copper-cladding layer, both the upper copper-cladding layer and the lower copper-cladding layer are divided into heat dissipation areas and circuit areas mutually isolated; the insulating plate is provided with a number of heat-conducting copper posts and electric copper posts that vertically penetrate the insulating plate; the upper ends of the heat-conducting copper posts are connected to the heat dissipation area of the upper copper-cladding layer, and the lower ends thereof are connected to the heat dissipation area of the lower copper-cladding layer; the upper ends of the electric copper posts are connected to the circuit area of the upper copper-cladding layer, and the lower ends thereof are connected to the circuit area of the lower copper-cladding layer; the circuit area surface of the upper copper-cladding layer is treated by roughening to form a roughened surface; the heat dissipation area surface of the lower copper-cladding layer is provided with convex-concave structures.

2. The high heat-dissipation LED substrate according to claim 1, wherein some part of the circuit area of the upper copper-cladding layer is provided with a soldering-suitable metal layer, and some other part is provided with a soldering-mask ink layer; the material of the soldering-suitable metal layer is one or more of nickel, silver, and gold.

3. The high heat-dissipation LED substrate according to claim 2, wherein the roughening method used for the circuit area surface of the upper copper-cladding layer is one or more of mechanical roughening method, electrolytic roughening method and corrosive roughening method.

4-5. (canceled)

6. The high heat-dissipation LED substrate according to claim 1, wherein the building method of the heat-conducting and electric copper posts is as follows: firstly drilling through holes at proper positions of the insulating plate, depositing a conductive carbon layer on the hole wall, then performing plating, to form the heat-conducting and electric copper posts, thus realizing the connection of the heat-conducting and electric copper posts to the corresponding heat dissipation areas and circuit areas.

7. The high heat-dissipation LED substrate according to claim 6, wherein the cross sections of the through holes are non-round.

8. The high heat-dissipation LED substrate according to claim 7, wherein the cross sections of the heat-conducting copper posts are 8-shaped or quincuncial, and the cross sections of the electric copper posts are 8-shaped or quincuncial.

9. The high heat-dissipation LED substrate according to claim 8, wherein a diameter of each continuous circular arc constituting 8-shaped or quincuncial form is 0.15-4 mm.

10. (canceled)

11. The high heat-dissipation LED substrate according to claim 8, wherein the roughening method used for the circuit area surface of the upper copper-cladding layer is one or more of mechanical roughening method, electrolytic roughening method and corrosive roughening method.

12. The high heat-dissipation LED substrate according to claim 8, wherein the roughening method used for the circuit area surface of the upper copper-cladding layer is one or more of mechanical roughening method, electrolytic roughening method and corrosive roughening method.

13. The high heat-dissipation LED substrate according to claim 1, wherein a heat conductivity of the insulating plate ranges from 80 W/(m·K) to 160 W/(m·K) a thickness of the insulating plate ranges from 0.1 mm to 0.4 mm, and an expansion coefficient of the insulating plate ranges from 5 m/K to 6 m/K or ranges from 8 m/K to 10 m/K.

14. A high heat-dissipation LED package, comprising one or more high heat-dissipation LED unit(s), wherein the high heat-dissipation LED unit comprises a high heat-dissipation substrate unit and a LED chip mounted on the high heat-dissipation substrate unit; the outside of the LED chip is provided with a transparent protection layer; the high heat-dissipation substrate unit uses the high heat-dissipation LED substrate according to claim 1, and the high heat-dissipation LED substrate contains at least one of the heat-conducting copper posts and at least two of the electric copper posts; the LED chip is located on the heat dissipation area of the upper copper-cladding layer and the positive and negative poles thereof are respectively connected to one of the electric copper posts; when there are a plurality of high heat-dissipation LED units, the high heat-dissipation substrate units of all of the high heat-dissipation LED units respectively correspond to different areas of the same high heat-dissipation LED substrate.

15. (canceled)

16. The high heat-dissipation LED package according to claim 15, wherein the LED chip and the heat dissipation area of the upper copper-cladding layer under it are bonded together by a high thermal conductive binder.

17. The high heat-dissipation LED package according to claim 14, wherein the roughening method used for the circuit area surface of the upper copper-cladding layer is one or more of mechanical roughening method, electrolytic roughening method and corrosive roughening method.

18. (canceled)

19. The high heat-dissipation LED package according to claim 14, wherein the building method of the heat-conducting and electric copper posts is as follows: firstly drilling through holes at proper positions of the insulating plate, depositing a conductive carbon layer on the hole wall, then performing plating to form the heat-conducting and electric copper posts, thus realizing the connection of the heat-conducting and electric copper posts to the corresponding heat dissipation areas and circuit areas; the cross sections of the through holes are non-round, the cross sections of the heat-conducting copper posts are 8-shaped or quincuncial, and the cross sections of the electric copper posts are 8-shaped or quincuncial.

20. The high heat-dissipation LED package according to claim 19, wherein the roughening method used for the circuit area surface of the upper copper-cladding layer is one or more of mechanical roughening method, electrolytic roughening method and corrosive roughening method.
